(19) United States
(12) Patent Application Publication
(10) Pub. No.: US 2011/0140081 A1
(43) Pub. Date: Jun. 16, 2011

(54) METHOD FOR FABRICATING SEMICONDUCTOR LIGHT-EMITTING DEVICE WITH DOUBLE-SIDED PASSIVATION

(75) Inventors: Fengyi Jiang, Jiangxi (CN); Li Wang, Jiangxi (CN)

(73) Assignee: LATTICE POWER (JIANGXI) CORPORATION, Nanchang, Jiangxi (CN)

(21) Appl. No.: 13/059,913

(22) PCT Filed: Aug. 19, 2008
(86) PCT No.: PCT/CN08/01490

§ 371 Date: Feb. 18, 2011

(51) Int. Cl. H01L 33/06; H01L 33/00

(52) U.S. Cl. 257/13; 438/26; 257/E33.008; 257/E33.001

(57) ABSTRACT

A method for fabricating a semiconductor light-emitting device includes fabricating a multilayer semiconductor structure on a first substrate, wherein the multilayer semiconductor structure comprises a first doped semiconductor layer, an MQW active layer, a second doped semiconductor layer, and a first passivation layer. The method further involves patterning and etching part of the first passivation layer to expose the first doped semiconductor layer. A first electrode is then formed, which is coupled to the first doped semiconductor layer. Next, the multilayer structure is bonded to a second substrate; and the first substrate is removed. A second electrode is formed, which is coupled to the second doped semiconductor layer. Further, a second passivation layer is formed, which substantially covers the sidewalls of multilayer structure and part of the surface of the second doped semiconductor layer which is not covered by the second electrode.

### BACKGROUND

1. Field of the Invention

The present invention relates to a method for fabricating semiconductor light-emitting devices. More specifically, the present invention relates to a method for fabricating novel semiconductor light-emitting devices with double-sided passivation that effectively reduces the leakage current and enhances the device reliability.

2. Related Art

Solid-state lighting is expected to bring the next wave of illumination technology. High-brightness light-emitting diodes (HB-LEDs) are emerging in an increasing number of applications, from serving as the light source for display devices to replacing light bulbs for conventional lighting. Typically, cost, efficiency, and brightness are the three foremost metrics for determining the commercial viability of LEDs.

An LED produces light from an active region which is “sandwiched” between a positively doped layer (p-type doped layer) and a negatively doped layer (n-type doped layer). When the LED is forward-biased, the carriers, which include holes from the p-type doped layer and electrons from the n-type doped layer, recombine in the active region. In direct band-gap materials, this recombination process releases energy in the form of photons, or light, whose wavelength corresponds to the band-gap energy of the material in the active region.

To ensure high efficiency of an LED, it is desirable to have the carriers recombine only in the active region instead of other places such as the lateral surface of the LED. However, due to the abrupt termination of the crystal structure at the lateral surface of the LED, there are large numbers of recombination centers on such surface. In addition, the surface of an LED is very sensitive to its surrounding environment, which may lead to added impurities and defects. Environmentally induced damage can severely degrade the reliability and stability of an LED. In order to insulate an LED from various environmental factors, such as humidity, ion impurity, external electrical field, heat, etc., and to maintain the functionality and stability of the LED, it is important to maintain the surface cleanness and to ensure reliable LED packaging. Moreover, it is also critical to protect the surface of an LED using surface passivation, which typically involves depositing a thin layer of non-reactive material on the surface of the LED.

FIG. 1 illustrates a traditional passivation method for an LED with a vertical-electrode configuration with, from the top down, a passivation layer 100, a n-side (or p-side) electrode 102, an n-type (or p-type) doped semiconductor layer 104, an active layer 106 based on a multi-quantum-well (MQW) structure, a p-type (or n-type) doped semiconductor layer 108, a p-side (or n-side) electrode 110, and a substrate 112.

The passivation layer reduces undesirable carrier recombination at the LED surface. For the vertical-electrode LED structure shown in FIG. 1, surface recombination tends to occur on the sidewalls of the MQW active region 106. However, the sidewall coverage by a conventional passivation layer, for example, layer 100 shown in FIG. 1, is often less than ideal. The poor sidewall coverage is typically a result of standard thin-film deposition techniques, such as plasma-enhanced chemical vapor deposition (PECVD) and magnetron sputtering deposition. The quality of sidewall coverage by the passivation layer is worse in devices with steeper steps, e.g., steps higher than 2 μm, which is the case for most vertical-electrode LEDs. Under such conditions, the passivation layer often contains a large number of pores, which can severely degrade its ability to reduce surface recombination of carriers. An increased surface recombination rate, in turn, increases the amount of the reverse leakage current, which results in reduced efficiency and stability of the LED. In addition, the metal that forms the p-side electrode can diffuse into the active region, leading to increased leakage current.

### SUMMARY

One embodiment of the present invention provides a method for fabricating a semiconductor light-emitting device. The method includes fabricating a multilayer semiconductor structure on a first substrate, wherein the multilayer semiconductor structure comprises a first doped semiconductor layer, an MQW active layer, a second doped semiconductor layer, and a first passivation layer. The method further involves patterning and etching part of the first passivation layer to expose the first doped semiconductor layer. A first electrode is then formed, which is coupled to the first doped semiconductor layer. Next, the multilayer structure is bonded to a second substrate; and the first substrate is removed. A second electrode is formed, which is coupled to the second doped semiconductor layer. Further, a second passivation layer is formed, which substantially covers the sidewalls of first and second doped semiconductor layers, the MQW active layer, and part of the surface of the second doped semiconductor layer which is not covered by the second electrode.

In a variation on this embodiment, the second substrate comprises at least one of the following materials: Cu, Cr, Si, and SiC.

In a variation on this embodiment, the first passivation layer comprises at least one of the following materials: GaN and AlN.

In a variation on this embodiment, the second passivation layer comprises at least one of the following materials: SiOₓ, SiNₓ, and SiOₓN_{y}.

In a variation on this embodiment, the first doped semiconductor layer is a p-type doped semiconductor layer.

In a variation on this embodiment, the second doped semiconductor layer is an n-type doped semiconductor layer.

In a variation on this embodiment, the MQW active layer comprises GaN and InGaN.

In a variation on this embodiment, the first substrate includes a predefined pattern of grooves and mesas.

In a variation on this embodiment, forming the second passivation layer involves at least one of the following processes: plasma-enhanced chemical vapor deposition (PECVD), magnetron sputtering deposition, and electron beam (e-beam) evaporation.

In a variation on this embodiment, the thickness of the first passivation layer is between 100 Å and 2,000 Å, and the thickness of the second passivation layer is between 300 Å and 10,000 Å.

### BRIEF DESCRIPTION OF THE FIGURES

FIG. 1 illustrates a traditional passivation method for an LED with a vertical-electrode configuration.

FIG. 2A illustrates part of a substrate with pre-patterned grooves and mesas in accordance with one embodiment of the present invention.

FIG. 2B illustrates the cross section of a pre-patterned substrate in accordance with one embodiment of the present invention.

FIG. 3 presents a diagram illustrating the process of fabricating a light-emitting device with double-sided passivation in accordance with one embodiment of the present invention.

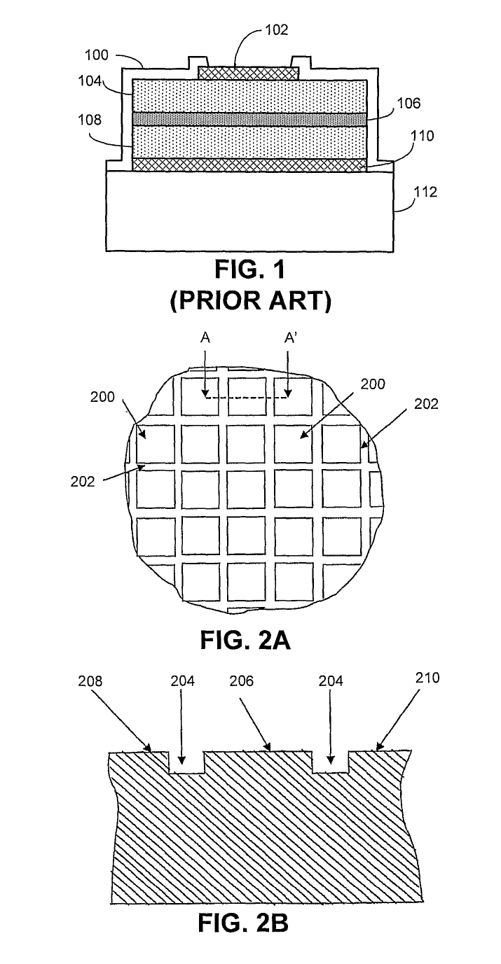

### DETAILED DESCRIPTION

The following description is presented to enable any person skilled in the art to make and use the invention, and is provided in the context of a particular application and its requirements. Various modifications to the disclosed embodiments will be readily apparent to those skilled in the art, and the general principles defined herein may be applied to other embodiments and applications without departing from the spirit and scope of the present invention. Thus, the present invention is not limited to the embodiments shown, but is to be accorded the widest scope consistent with the claims.

### Overview

Embodiments of the present invention provide a method for fabricating an LED device with double-sided passivation. Two sides of passivation which cover both the top and bottom sides of the device can effectively reduce surface recombination of the carriers, resulting in improved reliability of the LED device. In one embodiment of the present invention, instead of depositing only a single passivation layer at the outer surface of a multilayer semiconductor structure (which includes an n-typed doped layer, a p-type doped layer, and an active layer), two passivation layers (a top passivation layer and a bottom passivation layer) are deposited. The presence of the bottom passivation layer provides substantial insulation between the sidewalls of the active region and the p-side (or n-side) electrode. In one embodiment of the present invention, the bottom passivation layer is formed using the same deposition process that forms the multilayer structure, thus simplifying the fabrication process.

### Preparing the Substrate

InGaAlN (InₓGa_{y}Al_{1-x-y}N, 0<=x<=1, 0<=y<=1) is one of the optimal materials for manufacturing short-wavelength light-emitting devices. In order to grow a crack-free multilayer InGaAlN structure on a conventional large-area substrate (such as a Si wafer) to facilitate the mass production of high-quality, low-cost, short-wavelength LEDs, a growth method that pre-patterns the substrate with grooves and mesas is introduced. Pre-patterning the substrate with grooves and mesas can effectively release the stress in the multilayer structure that is caused by lattice-constant and thermal-expansion-coefficient mismatches between the substrate surface and the multilayer structure.

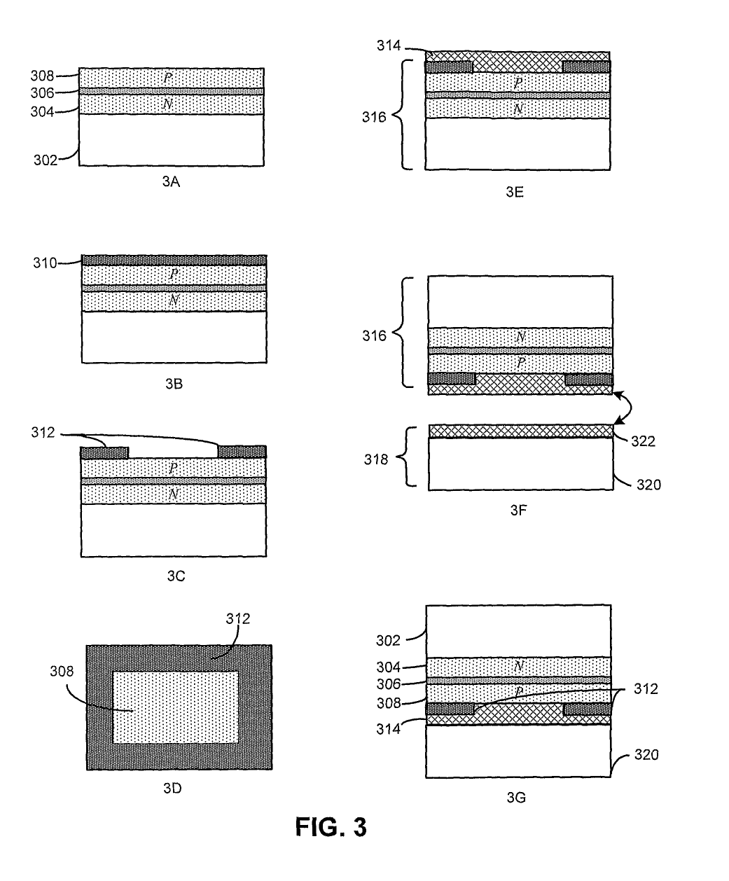

FIG. 2A illustrates a top view of a part of a substrate with a pre-etched pattern using photolithographic and plasma-etching techniques in accordance with one embodiment of the present invention. Square mesas 200 and grooves 202 are the result of the etching. FIG. 2B more clearly illustrates the structure of mesas and grooves by showing a cross section of the pre-patterned substrate along a horizontal line AA′ in FIG. 2A in accordance with one embodiment of the present invention. As seen in FIG. 2B, the sidewalls of grooves 204 effectively form the sidewalls of the isolated mesa structures, such as mesa 206, and partial mesas 208 and 210. Each mesa defines an independent surface area for growing a respective semiconductor device.

Note that it is possible to apply different lithographic and etching techniques to form the grooves and mesas on the semiconductor substrate. Also note that other than forming square mesas 200 as shown in FIG. 2A, alternative geometries can be formed by changing the patterns of grooves 202. Some of these alternative geometries can include, but are not limited to: triangular, rectangular, parallelogram, hexagon, circular, or other non-regular shapes.

Fabricating the Light-Emitting Device with Double-Sided Passivation

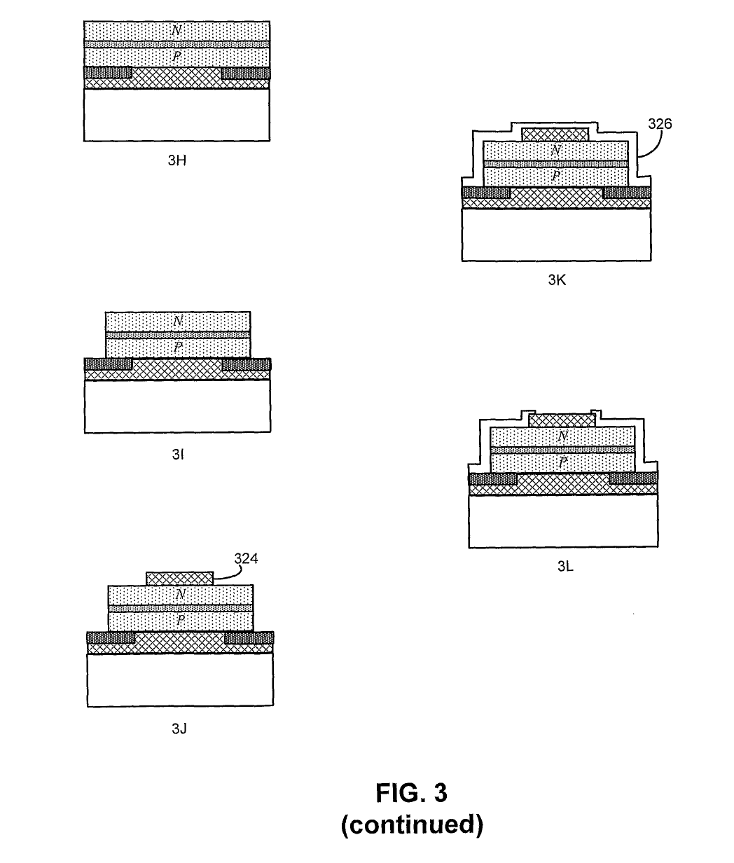

FIG. 3 presents a diagram illustrating the process of fabricating a light-emitting device with double-sided passivation in accordance with one embodiment of the present invention. In operation 3A, after a pre-patterned substrate with grooves and mesas is prepared, an InGaAlN multilayer structure can be formed using various growth techniques, which can include but are not limited to metalorganic-chemical-vapor-deposition (MOCVD). The fabricated LED structure can include a substrate 302, which can be a Si wafer; an n-type doped semiconductor layer 304, which can be a Si doped GaN layer; an active layer 306, which can be a GaN/InGaN MQW structure; and a p-type doped semiconductor layer 308, which can be a Mg doped GaN layer. Note that it is possible to reverse the sequence of the growth between the p-type layer and n-type layer.

In operation 3B, a first (bottom) passivation layer 310 is formed on the top of the p-type doped semiconductor layer using the same growth technique that forms the InGaAlN multilayer structure. In one embodiment of the present invention, bottom passivation layer 310 is formed using the same MOCVD growth technique. Using the same growth technique to form passivation layer 310 simplifies the fabrication process because now only one MOCVD growth step is needed to grow both the InGaAlN multilayer structure and the bottom passivation layer. Materials that can be used to form bottom passivation layer 310 include, but are not limited to: undoped GaN and undoped AlN. The thickness of the bottom passivation layer can fall between 100 and 2,000 angstroms. In one embodiment, the bottom passivation layer is approximately 500 angstroms thick. The figure corresponding to operation 3B shows the cross section after the deposition of the bottom passivation layer 310.

In operation 3C, photolithographic and etching techniques are applied to etch off part of passivation layer 312 exposing part of p-type doped layer 308. In one embodiment, the area to be etched off is selected such that both a sufficient area for electrical contact and a sufficient distance between the p-side electrode and edges of the device can be attained. Illustration 3D shows the top view of the multilayer structure after the partial etching of passivation layer 312. Note that the exposed area of p-type doped layer 308 can have other geometries than square. Because the material compositions of passivation layer 312 and p-type doped layer 308 are similar, a dry-etching technique can be used to etch part of passivation layer 312. However, under certain conditions, it is also possible to use a wet-etching technique to etch part of passivation layer 312. In one embodiment of the present invention, under certain growth conditions, the p-type doped layer 308 has a Ga-polar InGaAlN surface, and the undoped GaN passivation layer 312 has an N-polar surface. Therefore, a selective chemical etching can be used to etch off part of undoped GaN passivation layer 312 while leaving p-type passivation layer 308 substantially intact. In one embodiment of the present invention, an H₃PO₄ solution can be used to selectively etch off part of undoped GaN passivation layer 312.

In operation 3E, after the partial etching of bottom passivation layer 312, a metal layer 314 is deposited above multilayer structure 316 to form an electrode. If the top layer of the multilayered structure 316 is p-type doped material, then the electrode is a p-side electrode. The p-side electrode may include several types of metal such as nickel (Ni), gold (Au), platinum (Pt), and an alloy thereof. Metal layer 314 can be deposited using an evaporation technique such as electro-beam (e-beam) evaporation.

In operation 3F, multilayer structure 316 is flipped upside down to bond with a supporting conductive structure 318. Note that, in one embodiment, supporting conductive structure 318 includes a supporting substrate 320 and a bonding layer 322. In addition, a layer of bonding metal can be deposited on metal layer 314 to facilitate the bonding process. Supporting substrate layer 320 is conductive and may include silicon (Si), copper (Cu), silicon carbide (SiC), chromium (Cr), and other materials. Bonding layer 322 may include gold (Au). Illustration 3G shows the multilayer structure after bonding.

In operation 3H, substrate 302 is removed. Techniques that can be used for the removal of the substrate layer 302 can include, but are not limited to: mechanical grinding, dry etching, chemical etching, and any combination of the above methods. In one embodiment, the removal of substrate 302 is completed by employing a chemical-etching process, which involves submerging the multilayer structure in a solution based on hydrofluoric acid, nitric acid, and acetic acid. Note that supporting substrate layer 320 can be optionally protected from this chemical etching.

In operation 31, the edge of the multilayer structure is removed to reduce surface recombination centers and ensure high material quality throughout the entire device. However, if the growth procedure can guarantee a good edge quality of the multilayer structure, then this edge removal operation can be optional.

In operation 3J, after the edge removal, another electrode 324 is formed on top of the multilayer structure. Note that, because multilayer structure 312 was flipped upside down during the wafer-bonding process, the top layer is now the n-type doped semiconductor layer. Thus, the newly formed electrode is the n-side electrode 324. The metal composition and the forming process of the n-side electrode can be similar to that of the p-side electrode.

In operation 3K, a second (or top) passivation layer 326 is deposited. Materials that can be used to form the top passivation layer include, but are not limited to, the following: SiOₓ, SiNₓ, and SiOₓN_{y}. Various thin-film deposition techniques, such as PECVD and magnetron sputtering deposition, can be used to deposit the top passivation layer. The thickness of the top passivation layer can be between 300 and 10,000 angstroms. In one embodiment of the present invention, the top passivation layer has a thickness of approximately 2,000 angstroms.

In operation 3L, photolithographic patterning and etching are applied to top passivation layer 326 to expose the n-side electrode.

The foregoing descriptions of embodiments of the present invention have been presented only for purposes of illustration and description. They are not intended to be exhaustive or to limit the present invention to the forms disclosed. Accordingly, many modifications and variations will be apparent to practitioners skilled in the art. Additionally, the above disclosure is not intended to limit the present invention. The scope of the present invention is defined by the appended claims.

What is claimed is:

1. A method for fabricating a semiconductor light-emitting device, the method comprising:
fabricating a multilayer semiconductor structure on a first substrate, wherein the multilayer semiconductor structure comprises a first doped semiconductor layer, an MQW active layer, a second doped semiconductor layer, and a first passivation layer;
patterning and etching part of the first passivation layer to expose the first doped semiconductor layer;
forming a first electrode, which is coupled to the first doped semiconductor layer;
bonding the multilayer structure to a second substrate;
removing the first substrate;
forming a second electrode, which is coupled to the second doped semiconductor layer; and
forming a second passivation layer, which substantially covers the sidewalls of the first and second doped semiconductor layers, the MQW active layer, and part of the surface of the second doped semiconductor layer which is not covered by the second electrode.

2. The method of claim 1,
wherein the second substrate comprises at least one of the following materials:
Cu,
Cr,
Si, and
SiC.

3. The method of claim 1,
wherein the first passivation layer comprises at least one of the following materials:
undoped gallium nitride (GaN), and
undoped aluminum nitride (AlN).

4. The method of claim 1,
wherein the second passivation layer comprises at least one of the following materials:
silicon oxide (SiOₓ),
silicon nitride (SiNₓ), and
silicon oxynitride (SiOₓN_{y}).

5. The method of claim 1,
wherein the first doped semiconductor layer is a p-type doped semiconductor layer.

6. The method of claim 1,
wherein the second doped semiconductor layer is an n-type doped semiconductor layer.

7. The method of claim 1,
wherein the MQW active layer comprises GaN and InGaN.

8. The method of claim 1,
wherein the first substrate comprises a pre-defined pattern of grooves and mesas.

9. The method of claim 1,
wherein the second passivation layer is formed by one of the following processes:
plasma-enhanced chemical vapor deposition (PECVD),
magnetron sputtering deposition, and
e-beam deposition.

10. The method of claim 1,
wherein the thickness of the first passivation layer is between 100 Å and 2,000 Å, and wherein the thickness of the second passivation layer is between 300 Å and 10,000 Å.

11. A semiconductor light-emitting device, comprising:
a substrate;
a first doped semiconductor layer situated above the substrate;
a second doped semiconductor layer situated above the first doped semiconductor layer;
a multi-quantum-well (MQW) active layer situated between the first and the second doped semiconductor layers;
a first electrode coupled to the first doped semiconductor layer;
a first passivation layer, which is situated between the first electrode and the first doped semiconductor layer in areas other than an ohmic-contact area;
wherein the first passivation layer substantially insulates the first electrode from the edges of the first doped semiconductor layer, thereby reducing surface recombination; and
a second electrode coupled to the second doped semiconductor layer; and
a second passivation layer which substantially covers the sidewalls of the first and second doped semiconductor layer, the MQW active layer, and part of the horizontal surface of the second doped semiconductor layer which is not covered by the second electrode.

12. The semiconductor light-emitting device of claim 11,
wherein the substrate comprises at least one of the following materials:
Cu,
Cr,
Si, and
SiC.

13. The semiconductor light-emitting device of claim 11,
wherein the first passivation layer comprises at least one of the following materials:
gallium nitride (GaN), and
aluminum nitride (AlN).

14. The semiconductor light-emitting device of claim 11,
wherein the second passivation layer comprises at least one of the following materials:
silicon oxide (SiOₓ),
silicon nitride (SiN_{x,}), and
silicon oxynitride (SiOₓN_{y}).

15. The semiconductor light-emitting device of claim 11,
wherein the first doped semiconductor layer is a p-type doped semiconductor layer.

16. The semiconductor light-emitting device of claim 11,
wherein the second doped semiconductor layer is an n-type doped semiconductor layer.

17. The semiconductor light-emitting device of claim 11,
wherein the MQW active layer comprises GaN and InGaN.

18. The semiconductor light-emitting device of claim 11,
wherein the first and second doped semiconductor layers are grown on a substrate with a pre-defined pattern of grooves and mesas.

19. The semiconductor light-emitting device of claim 11,
wherein the second passivation layer is formed by at least one of the following processes:
plasma-enhanced chemical vapor deposition (PECVD),
magnetron sputtering deposition, or
electro-beam (e-beam) evaporation.

20. The semiconductor light-emitting device of claim 11,
wherein the thickness of the first passivation layer is between 100 and 2000 angstroms, and wherein the thickness of the second passivation layer is between 300 and 10,000 angstroms.
